(19) United States
(12) Patent Application Publication
(10) Pub. No.: US 2008/0221805 A1
(43) Pub. Date: Sep. 11, 2008

(54) MULTI-CHANNEL LOCK-IN AMPLIFIER SYSTEM AND METHOD

(76) Inventor: David Richard Andrews, Cambridgeshire (GB)

Correspondence Address: POLSINELLI SHALTON FLANIGAN SUELTHAUS PC, 700 W. 47TH STREET, SUITE 1000, KANSAS CITY, MO, 64112-1802, US

(21) Appl. No.: 12/045,397

(22) Filed: Mar. 10, 2008

Related U.S. Application Data
(60) Provisional application No. 60/893,944, filed on Mar. 9, 2007.

(51) Int. Cl. G01N 27/02; G01R 27/02

(52) U.S. Cl. 702/19; 324/713

(57) ABSTRACT

A multi-channel lock-in amplifier system for use in cell analysis is disclosed. The system may include a cartridge having one or more flow cells with each flow cell containing a cell for analysis. An oscillating electric field may be applied across each flow cell at one or more excitation frequencies in order to detect the responses of the cell either in electrical impedance at frequencies that provide a non-linear response.

### RELATED APPLICATIONS

This patent application claims priority from U.S. provisional patent application Ser. No. 60/893,944, filed on Mar. 9, 2007 and is herein incorporated by reference in its entirety.

### FIELD

This document relates to the field of cytometry, and more particularly to a cytometer system that uses a multi-channel lock-in amplifier to detect non-linear responses during a blood or cell analysis process.

### BACKGROUND

Cytometry involves the study of cells and their environment. Cytometers are available for analyzing or detecting certain characteristics of particles which are in motion. In typical flow cytometry instruments, blood cells or other biological material are caused to flow in a liquid stream so that each particle, preferably one at a time, passes through a sensing region which measures physical or chemical characteristics of the biological material. By detecting signals associated with different characteristics of the biological material, including electrical, magnetic, acoustical and radioactive, the type of material can be classified and/or analyzed to detect the presence of disease. As such, cytometry can be very useful in the field of blood analysis such as haematology.

Some conventional blood cell classification techniques involve determining an electrical impedance of the cell. Impedance is the ratio of

$$\frac{{V}_{N}}{{C}_{N}} ; \qquad ( 1 )$$

where V_{N} is the voltage applied across the network and C_{N} is the current through the network at a frequency, f, of interest.

There is generally a phase angle between the applied voltage and the resulting current flow. In pure resistors the phase angle is zero but in capacitors and inductors the phase angle is +/−90°. More complex networks have values of amplitude and phase of impedance that vary with frequency. It has been observed that white blood cells have this kind of varying impedance. As such, the variation of impedance with frequency can be used to infer blood cell types. One conventional method for using electrical impedance to identify a cell type is described in U.S. Pat. No. 6,437,551 to Krulevitch et al.

At around 1 MHz the impedance of blood cells in blood plasma develops a significant magnitude of imaginary part, that is the phase shift between the current and excitation voltage is non-zero (J Histochemistry & Cytometry 27 1 (1979) p 234-240 Hoffman & Britt), which then decreases at higher frequencies. There are two possible explanations for this behavior. One explanation is a purely electrical model in which the interior of the cell is a good conductor and the cell wall is a good insulator and, thus, presents a capacitance. However, although this would explain the increasing magnitude of imaginary part of impedance with frequency, it does not explain the decreasing imaginary part at higher frequencies. Another explanation is an electro-mechanical model, in which the cell wall is a good insulator and the interior of the cell is a good conductor as before, but the cell wall starts to vibrate mechanically and resonate due to induced electrical charges on the cell wall. The mechanical resonance of an ensemble of cells may not be particularly sharp, probably due to variations between different types of cells.

An analogous form of vibration to that described above is a bubble in a liquid. It is known that bubbles oscillate in a non-linear way because the adiabatic equation of state of any gas in the bubble is of the form:

pV^{γ}=cons tan t; (2)

where V is the volume of the bubble, p is the internal pressure and γ is the ratio of specific heats (Cₚ/Cᵥ). The equation shows that V does not vary linearly with p so the bubble oscillates non-linearly. For sufficiently small vibrations the non-linear effects are small and generally go unnoticed. A Taylor series expansion around any arbitrary state of pressure and volume (pₒ, Vₒ) shows the variation of volume (dV) with change of pressure (dp) becomes linear (a is a constant).

Vₒ+dV=α(pₒ^{-γ}−dpγpₒ^{-(γ+1)}) (3)

In the equation above a, γ, pₒ and Vₒ are all constants so,

dV∝−dp (4)

The equation is linear for small dp.

A cell has a wall that, although permeable to certain molecules, has some mechanical strength and is approximately impermeable to diffusion of molecules on the time-scale of electrical excitation at around 1 MHz, that is 0.5 μs. So it is reasonable to expect that its internal pressure will fluctuate as the cell vibrates, and those vibrations will be under adiabatic conditions. Consequently, it is expected that the motion of the cell will be increasingly non-linear as the amplitude of the oscillating electric field increases.

Conventional electrical impedance cytometry tests have focused: (1) exclusively upon the linear response of the cell by measuring the response at the same frequency as the excitation frequency thereby ignoring the non-linear response; or (2) using white noise for excitation, which contains, in principle, an infinite number of continuously distributed frequencies, and which generate an infinite number of non-linear response frequencies and thereby renders it impossible to detect the non-linear response caused by one or two specific excitation frequencies.

Neither of these approaches is capable of distinguishing specific, non-linear effects caused by specific frequencies.

### SUMMARY

The present multi-channel lock-in amplifier cytometry system can generate a large number of excitation frequencies that are precisely and digitally controlled in the range 100 kHz to 10 MHz. The system can detect at a number of receiving frequencies in the range 100 kHz to 10 MHz, each frequency being precisely and digitally controlled, at each frequency only a narrow band of frequencies (typically but not necessarily +/−10 kHz) is received and, most importantly, the receiving frequencies do not have to be the same value as the excitation frequencies.

Non-linear effects are manifest in two distinct and well-known ways. One method involves generation of sub-harmonics and harmonics. For example an excitation signal with an excitation frequency f generates responses at one or more of the frequencies 0.5 f, 2 f, 3 f, 4 f, 5 f. Another method involves mixing two frequencies, f₁ and f₂, to produce sum and difference frequencies (f₁+f₂) and (f₁−f₂).

This summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

Other features will be in part apparent and in part pointed out hereinafter.

### BRIEF DESCRIPTION OF THE DRAWINGS

FIG. 1A is an exemplary block diagram illustrating components of a multi-channel lock-in amplifier system according to one aspect of the invention.

FIG. 1B is a schematic diagram illustrating connection between a waveform synthesizer and electrodes of a microfluidic unit.

FIGS. 1C-1E depict relationships between the electric field for electrode configurations and the signal of impedance over time.

FIG. 1F depicts exemplary differential amplifier circuits for measuring voltage and current.

FIG. 2 depicts components of a lock-in amplifier circuit according to one aspect of the point of care diagnostic system.

FIG. 3 depicts components of a microprocessor for calculating an impedance of a biological sample.

FIG. 4 depicts an exemplary impedance histogram for blood cells and blood plasma.

Corresponding reference characters indicate corresponding parts throughout the drawings.

### DETAILED DESCRIPTION

The present invention relates to a point of care system and method for classifying a biological sample through an impedance measurement technique. More specifically, according to one aspect, the system and method involves applying an oscillating electric field via, for example, an oscillating voltage signal to a biological sample at one or more known excitation frequencies and detecting non-linear responses at sub-harmonic and harmonic frequencies of the excitation frequencies and/or non-linear responses at sum and difference frequencies of the excitation frequencies. The harmonic of a signal is a component frequency of the signal that is an integer multiple of its fundamental frequency. For example, if the excitation frequency is f, the harmonics have frequency 2 f, 3 f, 4 f, 5 f, etc. If there are two excitation frequencies f₁ and f₂, the sum and difference response frequencies correspond to (f₁+f₂) and (f₁−f₂), respectively.

It has been observed that applying an excitation or test signal to a cell at the excitation frequency, or test frequency, can lead to cell responses at a plurality of frequencies. When two or more excitation frequencies are used, the number of response frequencies increases rapidly. The present invention provides a point of care system and method to detect a plurality of responses at known, specific frequencies which are related to the excitation frequency or frequencies, but which may not necessarily be at the same frequency as the excitation frequency (e.g., harmonic frequencies and mixing frequencies).

In harmonic detection an electric field is made to oscillate at a frequency f. A lock-in amplifier is set to detect or receive signals at a harmonic off (e.g., 2 f, 3 f, 4 f, 5 f, etc.). If a blood cell responds non-linearly to the excitation of the electric field, it will respond by creating harmonics of the exciting frequency.

In mixed frequency detection, two excitation frequencies f₁ and f₂ are provided to generate an electric field. In this case, the lock-in amplifier is set to detect signals at the sum frequency (e.g., f₁+f₂) and difference frequency (e.g., f₁−f₂) of the excitation frequencies. If a blood cell responds non-linearly to the two excitation frequencies, it will respond by creating a response at the sum frequency and difference frequency of the excitation frequencies. By detecting both linear and non-linear impedance responses of a cell, the type and/or condition (e.g., diseased) of the cell can be more accurately identified.

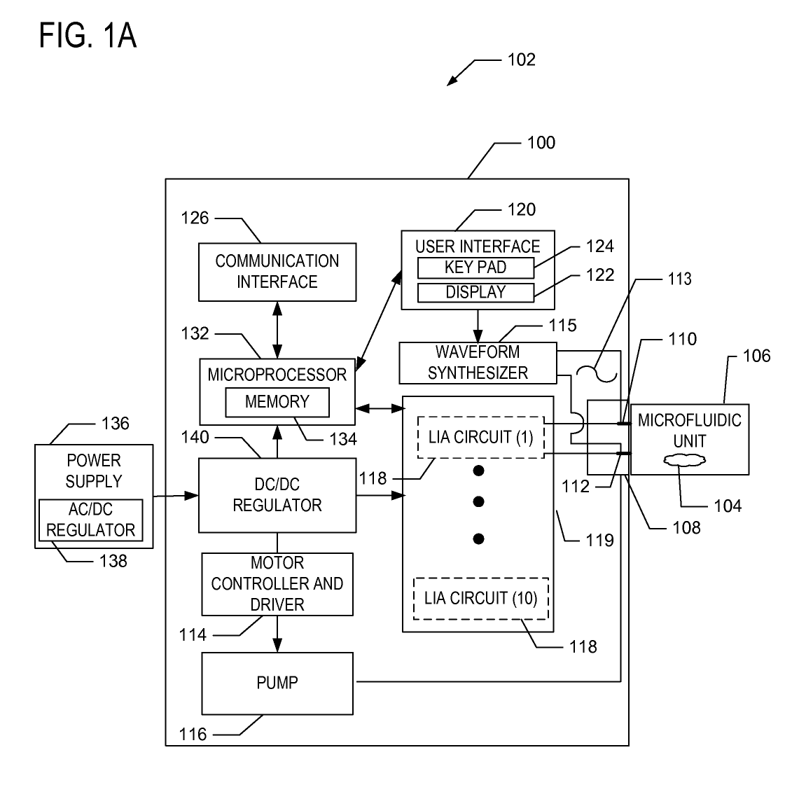

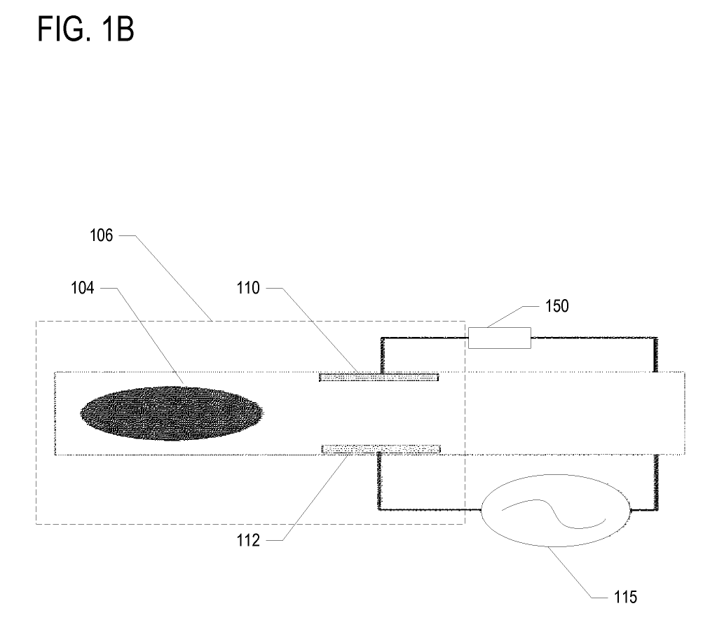

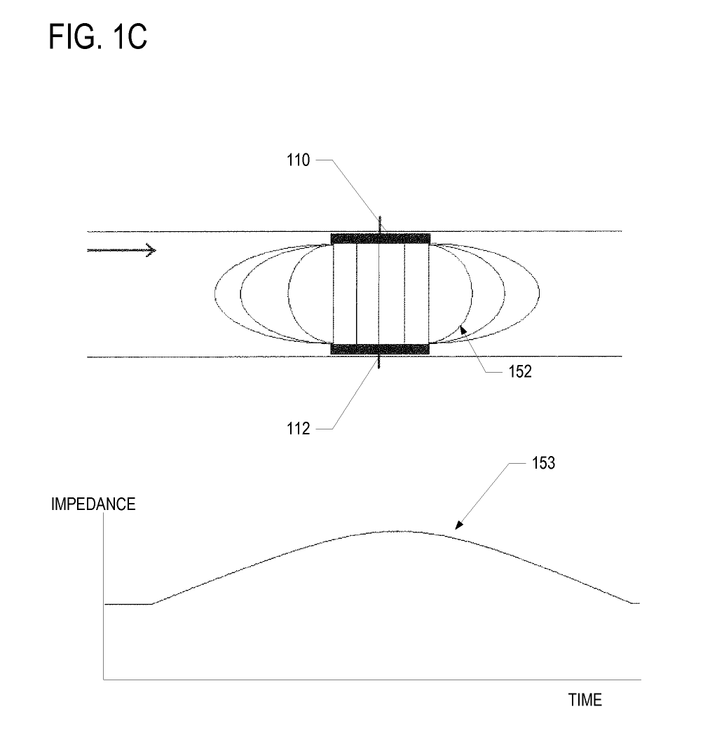

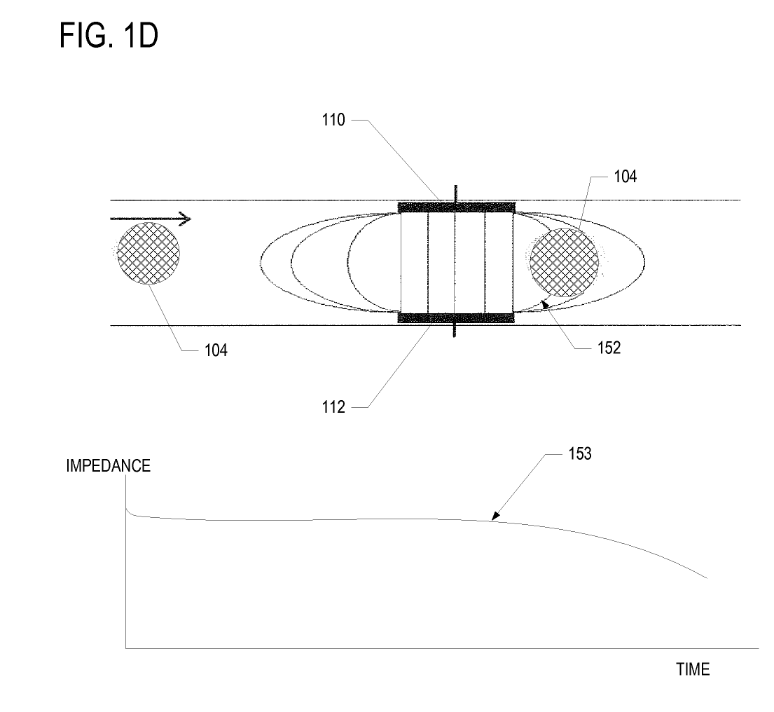

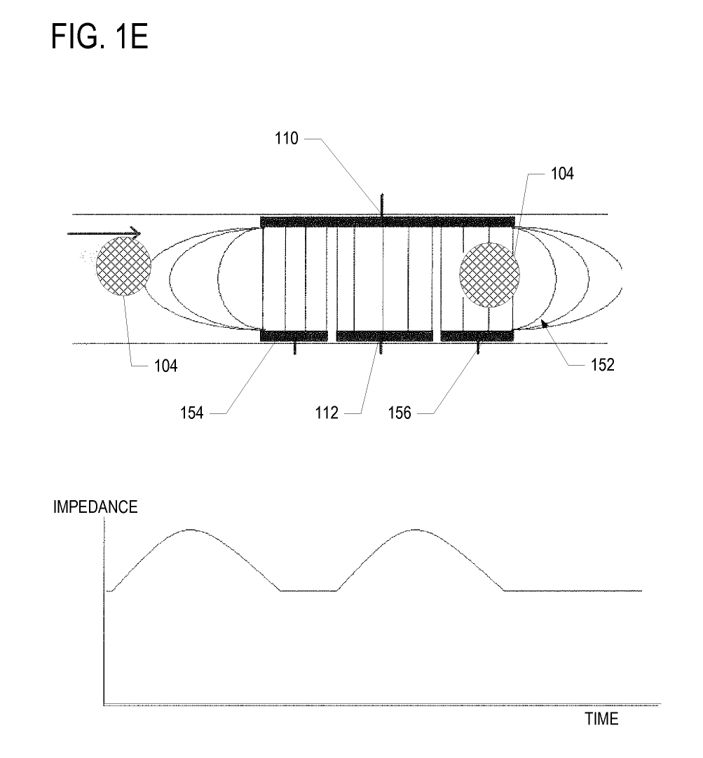

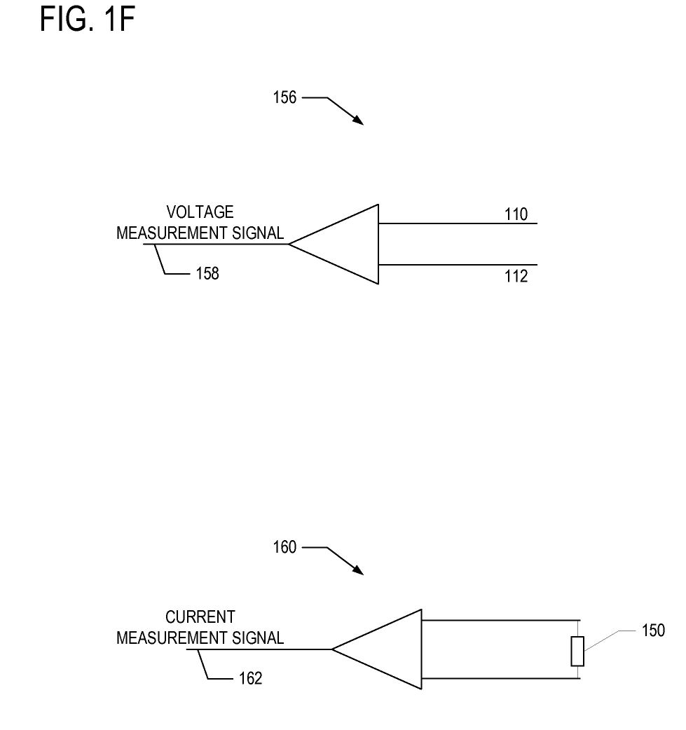

Referring to the drawings, FIG. 1A depicts components of a multi-channel lock-in amplifier (MCLIA) 100 for use with a point of care diagnostic system 102 for measuring a characteristic of a biological sample 104 such as a blood cell via an electrochemical detection process. Preferably, the components of the multi-channel lock-in amplifier 100 are encased in a housing (not shown).

According to one aspect, a disposable microfluidic cartridge unit 106 contains the biological sample 104 that will be subjected to the electrochemical detection process. For example, a sample transfer device (not shown) collects 50-200 μl of whole blood sample from a fingerstick or a vacutainer and subsequently transfers the sample to the microfluidic cartridge unit 106 for further processing. The microfluidic cartridge unit 106 can be a disposable closed container device that contains reagents, fluidic channels and biosensors that are necessary to generate assay results from a sample. The microfluidic cartridge unit 106 is configured to removably connect to an interface 108 of the MCLIA 100. The interface 108 comprises receptacles for receiving electrodes 110, 112 of the microfluidic cartridge unit 106 such that the MCLIA 100 can supply an oscillating signal 113 such as an oscillating voltage signal to the electrodes 110, 112. The oscillating voltage signal 113 produces an electric filled in the vicinity of the electrodes 110, 112.

The microfluidic unit 106 is further configured to pass the biological sample 104 (e.g., blood sample) through the electric field. For example, according to one aspect, the MCLIA 100 includes a controller/driver 114 that is configured to control a pump 116 that is configured to create fluid pressure within the microfluidic unit 106 (e.g., a capillary tube of the microfluidic unit 106) to drive blood cells in the microfluidic unit 106 through the electric field.

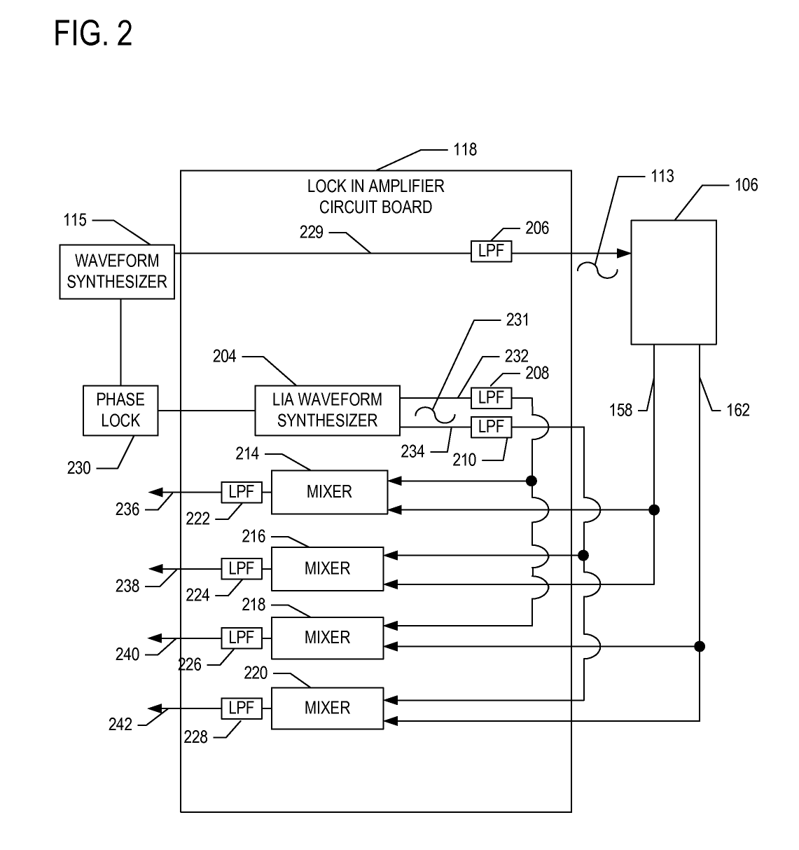

A waveform synthesizer 115, or alternatively a waveform generator, is configured to provide a programmable voltage signal (e.g., see synthesized output signal 228 in FIG. 2) to send to the electrodes 110, 112 of microfluidic unit 106 in the form of a superposition of sinusoidal waves (i.e., two signals 113) of different frequencies and amplitudes. The waveform synthesizer 115 is responsive to user input defining desired excitation frequencies and/or desired amplitudes of the oscillating voltage signals. The waveform synthesizer 115 is also configured to synthesize all of the test or excitation frequencies to apply to the electrodes 110, 112 of the microfluidic unit 106.

According to one aspect, the MCLIA 100 comprises ten (10) lock-in amplifier (LIA) circuits 118. Each of the LIA circuits 118 is configured to measure the voltage applied across the microfluidic electrodes 110, 112, the relative phase of the voltage across the microfluidic electrodes 110,112, a voltage from a differential amplifier sensing the current flow associated with biological sample 104 such as a blood cell, and the phase of the voltage relative to the voltage applied across the microfluidic electrodes 110, 112. Although the MCLIA 100 is described herein as comprising ten LIA circuits 118 connected to a LIA circuit board 119, it is contemplated that the MCLIA 100 is configured such that the number of LIA circuits 118 is scalable. If required, LIA circuits 118 can easily be added or removed, assuming the maximum processing limits of the microprocessor are not exceeded.

Referring now to FIG. 1B, a schematic diagram illustrates an example connection between the waveform synthesizer 115 and electrodes 110, 112 within a capillary tube of the microfluidic unit 106. The capillary includes a red blood cell 104 traveling from right to left. The waveform synthesizer 115 provides the oscillating signal 113 to the electrodes 110, 112. A resistor 150 is connected in series with the electrodes 110, 112. By monitoring the voltage across the electrodes 110, 112 and the current through the resistor 150, the impedance of the circuit can be monitored.

FIG. 1C depicts the relationship between the electric field 152 and the signal of impedance 153 against time. In the volume between the electrodes 110, 112 the electric field 152 lines are perpendicular to the electrodes 110, 112, and are straight and parallel. At the edges of the electrodes 110, 112 the field lines bulge out into the capillary tube. The presence of a blood cell 104 in the electric field 152 will result in the impedance between the electrodes 110, 112 changing (for the sake of example it is assumed that the impedance increases). The change in impedance happens when the blood cell 104 first reaches the outer limits of the electric field 152. The peak change in impedance happens when the blood cell 104 is in the middle of the electrodes 110, 112. The peak change in impedance is typically the measurement that is analyzed to detect the presence and condition of blood cells. The duration width of the peak impedance therefore depends upon the flow speed of the blood cell 104, the size of the blood cell 104, the width of the electrodes 110, 112 and the extent of the bulge in the electric field 152.

The electric field 152 between two charged conductors is described by Laplace's partial differential equation. At the edge of the conductors (e.g., electrodes 110, 112) there will be an uncontrolled diverging field pattern, which in the case of parallel plate electrodes causes a bulge in the electric field 152. The effect of the bulging electric field 152 is to increase the effective width of the electrodes 110, 112 and, consequently, to increase the duration of the peaks impedance as a blood cell 104 passes between the electrodes 110, 112. It is undesirable to have long duration peaks because it increases the probability that two or more peaks will overlap and it is difficult, if not impossible, to interpret overlapping peaks.

FIG. 1D depicts the relationship between the electric field 152 and the signal of impedance against time when two blood cells 104 are in the vicinity of the electrodes. The variation of impedance as a function of time includes contributions from all cells 104 that are within the range of the electric field 152, including the bulge in the field 152 at both ends. The impedance signal shown in FIG. 1D illustrates the summed contributions from both cells 104 near the field 152. The contributions of both cells 104 overlap to such an extent that it is difficult to draw a conclusion about either cell. However, the use of guard rings around the perimeter of the capillary tube enclosing the electrodes 110, 112 gives some improvement in the situation by effectively eliminating the bulging of fields 152 around the measurement electrode 112.

FIG. 1E depicts relationship between the electric field 152 and the signal of impedance 153 against time when guard rings 154, 156 (outer lower electrodes) are used and with two blood cells 104 in the vicinity of the electrodes 110, 112. Only the current flowing through the central electrode 112 is used to calculate impedance and the effect of the guard rings 154, 156 is to confine the field to the measurement electrode. With guard rings, the pulse from each blood cell is of shorter duration so the probability of two cells being close enough to result in overlapping impedance peaks is reduced and the probability of being able to measure the impedance of both blood cells is increased.

According to one aspect, differential amplifier circuits (see FIG. 1F) are connected to the interface 108 to monitor the voltage across the electrodes 110, 112 and the current can be measured as a function of the voltage across resistor 150 corresponding to the current through electrodes 110, 112. The two voltages will vary with frequency and vary as blood cells pass between the electrodes 110, 112 and differential voltage sensing amplifier circuits can be used by the LIAs for measuring the two voltages corresponding to the voltage across the electrodes and the current through the electrodes. For example, a voltage measurement circuit 156 such as depicted in FIG. 1F can be used to generate a voltage measurement signal 158 in response to the oscillating voltage signal applied to the electrodes 110, 112. An identical circuit 160 can be used to measure the voltage across the current sensing resistor 150, and generate current measurement signal 162. In this example, the current measurement signal is actually a voltage that can be used to determine current flow through the resistor 150.

Current can be measured either by the magnetic field it generates or by the voltage created as it passes through a known resistor (i.e., resistor 150) value, R. It is important that the value of R is of comparable value to the impedance between the capillary electrodes to ensure that the noise levels and errors of measurement are approximately the same for both voltage and current measurements; in this way the error in the final impedance value is minimized. Another differential amplifier circuit can be used to monitor the current change in response to the oscillating voltage as the blood cell passes between the electrodes. Both differential amplifiers also provide differential output signals that are sent to the microprocessor board and then to the LIAs. The differential signals are used to provide best rejection of electrical interference in the electrically noisy environment of the MCLIA.

Referring back to FIG. 1A, a user interface (UT) 120 enables a user of the MCLIA 100 to enter an excitation frequency and an amplitude of a voltage signal to apply to the electrodes 110, 112 and/or to view measurement data. According to one aspect, the UT 120 includes a display 122, such as a liquid crystal display (LCD), for displaying measurement data and includes an input device 124, such as a keyboard or keypad for defining or entering measurement parameter data. For example, the display 122 may display a power on status of the MCLIA 100, various menus, and measurement information such as voltage, current and impedance. The input device 124 may include an up button, a down button, a select button, and a cancel button for navigating and interacting with menus and displayed measurement values.

A communication interface 126 such as a universal serial bus (USB) port provides a user the ability to transfer measured data to an external computer readable medium 128 such as a flash drive or computing device. The transfer of such data to the computing device may occur via a communication network such as the Internet or a communication cable.

A microprocessor 132 is configured to communicate with each of the LIA circuits 118, to receive commands via the UT 120, and to display measurement data via the UT 120. For example, the microprocessor 132 is configured to control a frequency and attenuation of the signals applied to the electrodes 110, 112 by the LIA circuits 118 in response to user input, to sample the output signals of each of LIA circuits 118, and to calculate impedance values and store the impedance values in a memory 134. The microprocessor 132 is also configured to generate measured values and menu items for display on the display 122 and is connected to the communication interface 126 to transfer data to the external computer readable medium 128. According to one aspect, the microprocessor 1320 is TMS320F2812 32-bit fixed-point digital signal processors manufactured by Texas Instruments®.

A power supply 136 provides power to the operative components of the MCLIA 100. The power supply 136 receives main alternating current (AC) electrical power over the range of 110 v to 240 v at 50 Hz or 60 Hz and converts the AC power into direct current (DC) voltages required to operate the various components of the MCLIA 100. According to one aspect, the power supply 136 includes an AC to DC conversion component for converting an AC supply voltage to a DC supply voltage. For example, the power supply may include a power cord configured with a AC/DC power regulator 138 to provide DC voltage of approximately 12 volts at up to 5 amps to the MCLIA unit. A DC to DC power regulator 140 is coupled to the AC to DC conversion component an converts the DC supply voltage to lower DC voltages to provide power to the motor controller/driver 114, LIA circuits 118, the UT 120, and the microprocessor 132. It is further contemplated that the DC to DC power regulator 140 can be configured to output a plurality of lower DC voltages such that each component receives a requisite operating power input.

As a result, the multi-channel lock-in amplifier provides an improved cytometer system that allows the measurement of the non-linear response of a cell. Notably, although the invention is described herein in the context of detecting the type of blood cells, it is contemplated that the principles of the invention can be applied to other biological samples such as egg and sperm cells from humans and other animals, individual cells or small clusters of cells from other parts of the body of humans and animals, viruses and bacteria, individual cells or clusters of cells taken from any living species.

Although the MCLIA 100 is described above as comprising each LIA circuit 118 on a separate board (e.g., board 119), it is contemplated that in other aspects an integrated circuit comprises ten (10) LIAs and is on the same board as the microprocessor 132, memory 134, and other components.

FIG. 2 depicts components of the LIA circuit 118. For purposes of illustration, the following description corresponds to a single LIA circuit 118. Each of the plurality of LIA circuits 118 comprises one quadrature waveform synthesizer (LIA waveform synthesizer) 204, low-pass filters (LPFs) 206-210, mixer circuits 214-220 with corresponding LPFs 222-228.

The LIA waveform synthesizer 204 is configured to provide a programmable voltage signal to the electrodes 110, 112 of the microfluidic unit 106 in the form of a superposition of sinusoidal waves of different frequencies and amplitudes. As described above, the waveform synthesizer 115 is responsive to user input defining desired excitation frequencies and/or desired amplitudes of oscillating voltage signals to generates a synthesized output signal 229.

Each LIA waveform synthesizer 204 is phased-locked to the waveform synthesizer 115 used to drive the electrodes, as indicated by 230, and provides a voltage signal, as indicated by 231, with programmable frequency, known as the detection or receiving frequency. According to one aspect, the LIA waveform synthesizer 204 generates another synthesized output signal 232 that can optionally be set to a different frequency than the synthesized output signal(s) 229. For example, the frequency of the LIA waveform synthesizer 204 can be set to a harmonic of one of the frequencies of the main waveform synthesizer 115. The LIA waveform synthesizer 204 also generates a phase shifted synthesized output signal 234 that is 90° out of phase with the synthesized output signal 232. By using the LIA waveform synthesizer 204, harmonic detection can be achieved.

For example, consider that the main waveform synthesizer 115 is set to generate one frequency of 450 kHz and the detection or receiving frequency of a LIA waveform synthesizer 204 is 450 kHz, this is standard or linear lock-in amplifier detection. If the main waveform synthesizer 115 frequency is set to 450 kHz and the detection frequency of the LIA waveform synthesizer 204 is 900 kHz, this is known as 2^{nd} harmonic detection. As another example, if the main waveform synthesizer 115 frequency is set to 450 kHz and the LIA detection frequency of the LIA waveform synthesizer 204 is 2.25 MHz, this is known as 5^{th} harmonic detection.

According to one aspect, a plurality of mixers 214-220 are configured to multiply current and voltage signals (e.g., measurement signals 158, 162) from the microfluidic unit 106 with the synthesized output signal 232 and the phase shifted synthesized output signal 234. For example, a first mixer 214 is configured to multiply the synthesized output signal 232 by the voltage measurement signal 158 to create a first composite signal 236 A second mixer 216 is configured to multiply the −90° phase shifted, or quadrature, synthesized signal 234 by the voltage measurement signal 158 to create a second composite signal 238. A third mixer 218 is configured to multiply the synthesized output signal 232 by the voltage measurement signal 162 to create a third composite signal 240. A fourth mixer 220 is configured to multiply the −90° phase shifted, or quadrature, synthesized signal 234 by the voltage measurement signal 162 to create a fourth composite signal 242. Thereafter, the composite signals 236-242 can be filtered and processed by the microprocessor 132 to determine impedance data.

According to one aspect, LPFs 222-228 are connected to the outputs of mixers 214-220 to filter the output signals 236-242. More specifically, each of the LPFs 222-228 removes noise outside of the pass band of the low-pass filter to optimize the signal-to-noise ratio. The resulting signals are used to calculate the amplitude, R, and phase, q of the signal. For example, assume signals Q1 and Q2 are output from low-pass filters and, the amplitude, R, and phase, φ, of the signal can be calculated as follows

R=SQRT(Q1² and Q2²) φ=tan⁻ⁱ(Q₂/Q,) (5)

According to another aspect, the LPF 206 is connected to the output of the waveform synthesizer 115 and LPFs 208, 210 are connected to the outputs of the LIA waveform synthesizer.

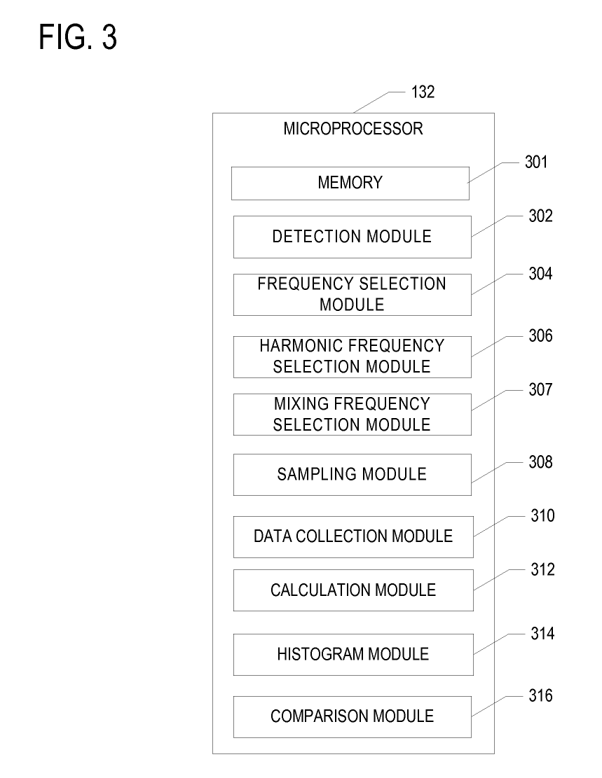

FIG. 3 depicts components of the microprocessor 132 for classifying and/or analyzing a biological sample 104 based on a calculated impedance. The microprocessor 132 comprises executable modules or instructions for controlling the LIA circuits 118 and processing sensed voltage and current levels to calculate impedance values.

A memory 301 (e.g., memory 134) is configured to store measured voltage and current data as well as calculated impedance data. A separate memory (not shown) such as a FLASH memory or ROM may comprise the executable modules. Generally, the modules are loaded into Static Random Access Memory (SRAM) when the microprocessor 132 firsts starts or boots.

According to one aspect, a detection module 302 is configured to detect the connection of the microfluidic unit 106 to the MCLIA 100 and to display a menu to the user via the UI 120 that enables a user initiate analysis of the biological sample 104. Other menus may allow the user perform other function such as enter desired test, or excitation, frequencies for the waveform synthesizer 115, enter receiving or test frequencies for the LIA waveform synthesizer 204, and/or select a detection mode (e.g., harmonic or frequency mixing).

A frequency selection module 304 is configured to set a frequency and amplitude of the main waveform synthesizer 115 to a desired frequency in response to input from the user. The main waveform synthesizer 115 generates a synthesized output signal 229 as described above that is filtered and applied to the electrodes 110, 112.

The harmonic frequency selection module 306 is configured to set a detection frequency for each LIA waveform synthesizer 204 to a sub-harmonic, a second harmonic, third harmonic, a fourth harmonic, or a fifth harmonic, etc. of the excitation frequency or possibly the linear or fundamental frequency in response to input from the user. For example, the user interacts with the UT 120 to select a harmonic detection mode. Each LAI waveform synthesizer 204 generates a synthesized output signal 232 and a −90° phase shifted synthesized output signal 234 as described above that are multiplied by measured voltage and current signals (e.g., measurement signals 158, 162) to create composite signals 236-242.

By way of example, according to aspects of the MCLIA 100 it is possible to provide 3 excitation frequencies: 100 kHz, 1 MHz, and 3.4 MHz, it would also be possible to provide the following frequencies:

100 kHz—linear response to 100 kHz excitation.

200 kHz—2^{nd} harmonic response to 100 kHz excitation.

500 kHz—sub-harmonic response to 1 MHz excitation.

1 MHz—linear response to 1 MHz excitation.

1.7 MHz—sub-harmonic response to 3.4 MHz excitation.

2 MHz—2^{nd} harmonic response to 1 MHz excitation.

3 MHz—3^{rd} harmonic response to 1 MHz excitation.

3.4 MHz—linear response to 3.4 MHz excitation.

6.8 MHz—2^{nd} harmonic response to 3.4 MHz excitation.

The above list is not an exhaustive list of all possibilities but serves to illustrate the plurality of possibilities but also the precision in frequency value with which the responses are known.

A mixing frequency selection module 307 is configured to set a detection frequency for each LIA waveform synthesizer 204 to a sum or difference of two excitation frequencies f1, f2 in response to input from the user. For example, the user interacts with the UI 120 to select a mix frequency detection mode. The mixing frequency selection module 307 is configured to set a first frequency f1 and a second frequency f1 for the main waveform synthesizer 115 in response to input from the user. The mixing frequency selection module 307 is configured to control the main waveform synthesizer 115 to provide two synthesized output signals (e.g., two synthesized output signal 222) to the electrodes 110, 112. One of the synthesized output signals has the frequency f1 and the other synthesized output signals have the frequency f2.

For example, using the three (3) example frequencies provide above 100 kHz, 1 MHz, and 3.4 MHz, it would also be possible to detect the following mixing frequencies:

890 kHz—mixing response of (1 MHz−110 kHz).

1.11 MHz—mixing response of (1 MHz+110 kHz).

2.4 MHz—mixing response of (3.4 MHz−1 MHz).

3.29 MHz—mixing response of (3.4 MHz−110 kHz).

3.51 MHz—mixing response of (3.4 MHz+110 kHz).

A sampling module 308 is configured to sample the composite signals 236-242. Typically, only one of the composite signals 236-242 is sampled at a particular point in time for measurement. However, by keeping the sampling speed sufficiently high the change of impedance with time (as a blood cell passes through the electrodes) will be accurately measured. It is assumed it takes about 1 milli-second (ms) for a blood cell to pass through the electrodes. According to one aspect, the sampling module 308 is configured to sample the composite signals 236-242 of each LIA at least four (4) times per 1 ms. According to another aspect, it is proposed that the maximum sampling speed will be 10 times per 1 ms. An impedance measurement is made by combining the results for voltage and current.

A data collection module 310 collects the sampled data comprising voltage levels and current levels for the linear and non-linear responses and stores the sampled voltage and current data in the memory 301. A linear response corresponds to when the detection frequency is at the same as the excitation frequency and a non-linear response corresponds to when the detection frequency is at a harmonic of the excitation frequency.

A calculation module 312 calculates impedance of the biological sample as a function of the sampled voltage and current data. As described above, impedance can be determined by the ratio of a measured voltage and measured current in the circuit (see equation 1).

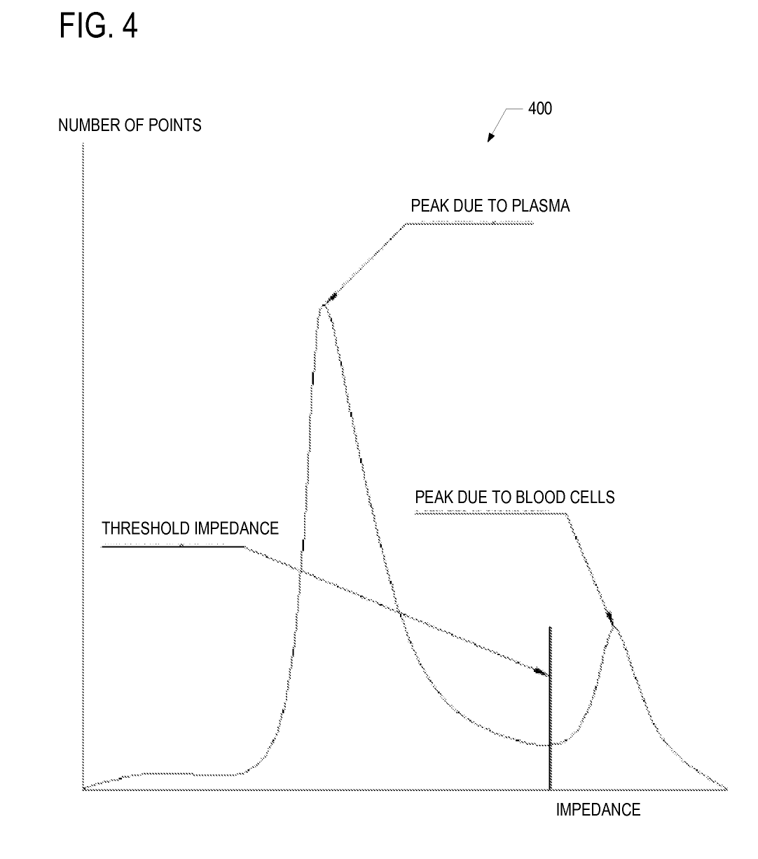

A histogram module 314 defines an impedance based on the sampled voltage and current data stored in the memory 301. According to one aspect the histogram shows impedance against the number of sampled points. Because impedance can be used to discriminate between types of biological samples, a threshold level can be defined based on the analysis of historical biological data for known biological samples. This threshold level can be stored in the memory and applied to the generated histogram to identify the type of biological sample. For example, the impedance histogram 400, such as depicted in FIG. 4, provides the ability to discriminate between blood cells and blood plasma. A first peak in the histogram 400 may represent plasma and a second peak (or peaks) may represent blood cells. Accordingly, if there is good grouping of plasma values and blood cells, a threshold impedance value can be set to differentiate between blood cells and blood plasma.

A comparison module 316 compares the calculated impedance to linear and non-linear histogram data to determine a type of the biological sample (e.g., blood cell or blood plasma) and/or whether a disease is present in the biological sample. For example, by comparing the calculated impedance of a blood cell to linear and non-linear histogram data of blood cells having known diseases, the comparison module 316 can identify matching data to determine whether the biological sample is diseased.

In operation, the MCLIA executes computer-executable modules such as those illustrated the FIG. 3 to implement embodiments of the invention.

The order of execution or performance of the operations in embodiments of the invention illustrated and described herein is not essential, unless otherwise specified. That is, the operations may be performed in any order, unless otherwise specified, and embodiments of the invention may include additional or fewer operations than those disclosed herein. For example, it is contemplated that executing or performing a particular operation before, contemporaneously with, or after another operation is within the scope of embodiments of the invention.

Embodiments of the invention may be implemented with computer-executable instructions. The computer-executable instructions may be organized into one or more computer-executable components or modules. Aspects of the invention may be implemented with any number and organization of such components or modules. For example, aspects of the invention are not limited to the specific computer-executable instructions or the specific components or modules illustrated in the figures and described herein. Other embodiments of the invention may include different computer-executable instructions or components having more or less functionality than illustrated and described herein.

When introducing elements of aspects of the invention or the embodiments thereof, the articles “a,” “an,” “the,” and “said” are intended to mean that there are one or more of the elements. The terms “comprising,” “including,” and “having” are intended to be inclusive and mean that there may be additional elements other than the listed elements.

As various changes could be made in the above constructions, products, and methods without departing from the scope of aspects of the invention, it is intended that all matter contained in the above description and shown in the accompanying drawings shall be interpreted as illustrative and not in a limiting sense.

What is claimed is:

1. A multi-channel lock-in amplifier system for analyzing a biological sample comprising:
an electrical interface to connect to electrodes of a microfluidic unit, the microfluidic unit containing the biological sample;
a first waveform synthesizer configured to generate at least one test signal having at least one test frequency to apply to the electrodes to create an electric field in the microfluidic unit;
a plurality of lock-in amplifier (LIA) circuits each configured to:
apply a receiving oscillating signal having a receiving frequency to the electrodes;
measure a voltage signal and a current signal generated in the microfluidic unit as the biological sample passes through the electric field; and
multiply the voltage signal and the current signal by the receiving oscillating signal having the receiving frequency to create a plurality of composite signals, the receiving frequency comprising a harmonic of the test frequency;
a processor to configured to:
calculate impedance data of the biological sample as a function of the plurality of composite signals;
retrieve historical impedance data corresponding to the biological sample from a memory;
compare the calculated impedance data to the historical impedance data to determine a type of the biological sample; and
a display to generate the calculated impedance for display.

2. The multi-channel lock-in amplifier system of claim 1 wherein multiplying the voltage signal and the current signal by the receiving oscillating signal having the receiving frequency enables the detection of a non-linear response from the biological sample.

3. The multi-channel lock-in amplifier system of claim 1 wherein each of the plurality of lock-in amplifier (LIA) circuits comprises:
a second waveform synthesizer to generate the receiving oscillating signal; and
a plurality of mixers each configured to one of the voltage signal and the current signal by the receiving oscillating signal to create the plurality of composite signals.

4. The multi-channel lock-in amplifier system of claim 3 wherein the receiving oscillating signal comprises a synthesized output component and a phase shifted synthesized output component, and wherein:
a first mixer is configured to multiply the voltage signal by the synthesized output component to create a first composite signal;
a second mixer is configured to multiply the current signal by the synthesized output component to create a second composite signal;
a third mixer is configured to multiply the voltage signal by the phase shifted synthesized output component to create a third composite signal; and
a fourth mixer is configured to multiply the current signal by the phase shifted synthesized output component to create a fourth composite signal.

5. The multi-channel lock-in amplifier system of claim 1 wherein the historical data corresponds to histogram data of voltage and current data for the biological sample.

6. The multi-channel lock-in amplifier system of claim 1 wherein the first waveform synthesizer is configured to generate a first test signal and a second test signal to apply to the electrodes to create an electric field in the microfluidic unit, the first test signal having a first test frequency and the second test signal having a second test signal, and wherein the receiving frequency comprises a sum of the first and second test frequencies or a difference of the first and second test frequencies.

7. The multi-channel lock-in amplifier system of claim 1 further comprising a user interface to control the LIA circuit to generate the receiving oscillating signal having the receiving frequency in response to input from a user.

8. The multi-channel lock-in amplifier system of claim 7 wherein the test frequency is an excitation frequency and wherein the processor is configured to select the receiving frequency of the receiving oscillating signal from the group consisting of a sub-harmonic, a fundamental, and a harmonic.

9. The multi-channel lock-in amplifier system of claim 1 wherein the processor is further configured to compare the calculated impedance data to the historical impedance data to determine if a disease is present in the biological sample.

10. A point of care system comprising a multi-channel lock-in amplifier (MCLIA) for analyzing a biological sample, the MCLIA comprising:
an electrical interface to connect to electrodes of a microfluidic unit, the microfluidic unit containing the biological sample;
a first waveform generator configured to generate at least one excitation signal having an excitation frequency to apply to the electrodes to create an electric field in the microfluidic unit;
a plurality of lock-in amplifier (LIA) circuits each configured to:
to measure a voltage signal and a current signal generated in the microfluidic unit as the biological sample passes through the electric field; and
to multiply the voltage signal and the current signal by a receiving oscillating signal having a receiving frequency to create a plurality of composite signals, the receiving frequency comprising a harmonic of the excitation frequency; and
a processor comprising modules executable on the processor, the modules comprising:
a detection module configured to detect the connection of the microfluidic unit to the MCLIA to display a menu to a user via a user interface;
a frequency selection module configured to set the excitation frequency in response to input from the user via the user interface;
a harmonic frequency selection module configured to set the receiving frequency to a harmonic of the excitation frequency;
a sampling module configured to sample current data and voltage data from the plurality of composite signals;
a data collection module configured to collect the sampled data comprising voltage and current for linear and non-linear responses and to store the sampled voltage and current data in a memory;
a calculation module configured to calculate impedance of the biological sample as a function of the sampled voltage and current data; and
a comparison module configured to compare the calculated impedance to historical linear and non-linear data to determine a type of the biological sample.

11. The system of claim 10 wherein multiplying the voltage signal and the current signal by a receiving oscillating signal having the receiving frequency enables the detection of a non-linear response from the biological ample.

12. The system of claim 10 wherein each of the plurality of LIA circuits comprises:
a second waveform generator to generate the receiving oscillating signal; and
a plurality of mixers each configured to multiple one of the voltage signal and the current signal by the receiving oscillating signal to create the plurality of composite signals.

13. The system of claim 12 wherein the receiving oscillating signal comprises a synthesized output component and a phase shifted synthesized output component, and wherein:
a first mixer configured to multiply the voltage signal by the synthesized output component to create a first composite signal;
a second mixer configured to multiply the current signal by the synthesized output component to create a second composite signal;
a third mixer configured to multiply the voltage signal by the phase shifted synthesized output component to create a third composite signal; and
a fourth mixer configured to multiply the current signal by the phase shifted synthesized output component to create a fourth composite signal.

14. The system of claim 10 further comprising a histogram module configured to generate a histogram based on the historical linear and non-linear data voltage current data, and wherein the comparison module compares the calculated impedance to historical linear and non-linear data defined by the histogram to determine the type of the biological sample.

15. The system of claim 10 wherein the first waveform generator is configured to generate a first excitation signal and a second excitation signal to apply to the electrodes to create an electric field in the microfluidic unit, the first excitation signal having a first excitation frequency and the second excitation signal having a second excitation frequency, and wherein the receiving frequency comprises a sum of the first and second excitation frequencies or a difference of the first and second excitation frequencies.

16. The system of claim 10 wherein the first frequency is an excitation frequency and wherein the processor is configured to select the receiving frequency of the receiving oscillating signal from the group consisting of a sub-harmonic, a fundamental frequency, or a harmonic.

17. The system of claim 10 wherein the comparison module is further configured to compare the calculated impedance data to the historical impedance data to determine if a disease is present in the biological sample.

18. A method for analyzing a biological sample contained in a microfluidic unit, the method comprising:
creating an electric field in the microfluidic unit by applying at least one test signal to electrodes of the microfluidic unit, the at least one test signal having a test frequency;
applying a receiving oscillating signal having a receiving frequency to the electrodes;
measuring a voltage signal and a current signal generated in the microfluidic unit as the biological sample passes through the electric field;
multiply the voltage signal and the current signal by the receiving oscillating signal having the receiving frequency to create a plurality of composite signals, the receiving frequency comprising a harmonic of the test frequency;
calculating impedance data of the biological sample as a function of the plurality of composite signals;
retrieving historical impedance data corresponding to the biological sample from a memory;
comparing the calculated impedance data to the historical impedance data to determine a type of the biological sample; and
generating the calculated impedance for display.

19. The method of claim 18 further comprising:
generating the receiving oscillating signal at a second waveform generator; and
multiplying one of the voltage signal and the current signal by the receiving oscillating signal via each of a plurality of mixers to create the plurality of composite signals.

20. The method of claim 19 wherein the receiving oscillating signal comprises a synthesized output component and a phase shifted synthesized output component, and wherein the method further comprises:
multiplying the voltage signal by the synthesized output component at a first mixer to create a first composite signal;
multiplying the current signal by the synthesized output component at a second mixer to create a second composite signal;
multiplying the voltage signal by the phase shifted synthesized output component at a third mixer to create a third composite signal; and
multiplying the current signal by the phase shifted synthesized output component at a fourth mixer to create a fourth composite signal.

21. The method of claim 18 wherein creating the electric field comprises generating a first test signal and a second test signal to apply to the electrodes to create the electric field in the microfluidic unit, the first test signal having a first test frequency and the second test signal having a second test frequency, and wherein the receiving frequency comprises a sum of the first and second test frequencies or a difference of the first and second test frequencies.

22. A multi-channel lock-in amplifier (MCLIA) for analyzing a blood cell comprising:
an electrical interface to connect to electrodes of a microfluidic unit, the microfluidic unit containing the blood cell;
a first waveform generator configured to generate a first excitation signal and a second excitation signal to apply to the electrodes to create an electric field in the microfluidic unit, the first excitation signal having a first excitation frequency and the second excitation signal having a second excitation frequency;
a plurality of lock-in amplifier (LIA) circuits each configured to:
to measure a voltage signal and a current signal generated in the microfluidic unit as the blood cell passes through the electric field; and
to multiply the voltage signal and the current signal by a receiving oscillating signal having a receiving frequency to create a plurality of composite signals, the receiving frequency comprising a sum of the first and second excitation frequencies or a difference of the first and second excitation frequencies; and
a processor comprising modules executable on the processor, the modules comprising:
a detection module configured to detect the connection of the microfluidic unit to the MCLIA to display a menu to a user via a user interface;
a frequency selection module configured to set the excitation frequency in response to input from the user via the user interface;
a mixing frequency selection module configured to set the receiving frequency to the sum of the first and second excitation frequencies or the difference of the first and second excitation frequencies;
a sampling module configured to sample current data and voltage data from the plurality of composite signals;
a data collection module configured to collect the sampled data comprising voltage and current for linear and non-linear responses and to store the sampled voltage and current data in a memory;
a calculation module configured to calculate impedance of the blood cell as a function of the sampled voltage and current data; and
a comparison module configured to compare the calculated impedance to historical linear and non-linear data to determine a type of the blood cell.

23. The MCLIA of claim 22 wherein multiplying the voltage signal and the current signal by the receiving oscillating signal having the receiving frequency enables the detection of a non-linear response from the blood cell.

24. The MCLIA of claim 22 further comprising a histogram module configured to generate a histogram based on the historical linear and non-linear data voltage current data, and wherein the comparison module compares the calculated impedance to historical linear and non-linear data defined by the histogram to determine the type of the blood cell.

25. The MCLIA of claim 22 wherein the comparison module is further configured to compare the calculated impedance data to the historical impedance data to determine if a disease is present in the blood cell.
